(19) United States
(12) Patent Application Publication
(10) Pub. No.: US 2008/0159048 A1
(43) Pub. Date: Jul. 3, 2008

(54) SEMICONDUCTOR MEMORY DEVICE HAVING POWER SUPPLY WIRING NETWORK

(75) Inventor: Tatsuya MATANO, Tokyo (JP)

Correspondence Address: Young & Thompson, Second Floor, 745 S. 23rd Street., Arlington, VA, 22202, US

(73) Assignee: ELPIDA MEMORY, INC., Tokyo (JP)

(21) Appl. No.: 11/959,646

(22) Filed: Dec. 19, 2007

(30) Foreign Application Priority Data
Dec. 22, 2006 (JP) 2006-346029

(51) Int. Cl. G11C 5/14

(52) U.S. Cl. 365/227

(57) ABSTRACT

A semiconductor memory device according to the present invention comprising: a plurality of memory banks; n internal voltage generation circuits for active state each provided to one or more memory banks, activated when corresponding memory bank(s) are in an active state, and deactivated when corresponding memory bank(s) are in a standby state, where n is an integer more than 1; m internal voltage generation circuits for standby state each provided to one or more memory banks, activated when corresponding memory bank(s) are at least in the standby state, where m is an integer more than 1; and a power supply wiring network supplying an internal voltage generated by the internal voltage generation circuits for active state and the internal voltage generation circuits for standby state to the corresponding memory banks.

### TECHNICAL FIELD

The present invention relates to a semiconductor memory device, and more particularly to a semiconductor memory device in which a plurality of memory banks are arranged in a distributed fashion.

### BACKGROUND OF THE INVENTION

A semiconductor memory device typified by a DRAM (Dynamic Random Access Memory) is often configured so that a memory cell array is divided into a plurality of memory banks so as to enable parallel operations inside. Commands can be individually issued from outside of the semiconductor memory device to the respective memory banks. The memory banks have different active periods accordingly.

Each of the memory banks differs in power consumption between an active state and a standby state. Due to this, if a supply capability of an internal voltage generation circuit that supplies an internal voltage to each memory bank is designed so as to supply enough power to the memory bank in the active state, power consumption is wasted in the standby state. Conversely, if the supply capability of the internal voltage generation circuit is designed so as to supply enough power to the memory bank in the standby state, the capability is insufficiently in the active state. Normally, therefore, both an internal voltage generation circuit for standby state that is constantly activated and an internal voltage generation circuit for active state that is activated only while the corresponding memory bank is active state are employed (see Japanese Patent Application Laid-Open No. 2006-127727).

Generally, each internal voltage generation circuits for active state is arranged near a corresponding memory bank and starts supplying the internal voltage when the corresponding memory bank is brought into the active state. On the other hand, only one internal voltage generation circuit for standby state is arranged per chip and continuously and constantly supplies the internal voltage to a power supply wiring network formed in every direction on the chip.

However, the conventional semiconductor memory devices have the following disadvantages. Recently, density of semiconductor memory devices has been increased and a performance thereof has been improved. Due to this, the number of power supply wirings that can be arranged in peripheral circuit regions is often restricted. In this case, the power supply wiring network is configured to include sub-wiring networks. This may disadvantageously make voltage of the power supply wiring network unstable in the standby state.

### SUMMARY OF THE INVENTION

It is therefore an object of the present invention to stabilize the internal voltage in a semiconductor memory device in which a power supply wiring network is configured to include sub-wiring networks.

The above and other objects of the present invention can be accomplished by a semiconductor memory device comprising: a plurality of memory banks; n internal voltage generation circuits for active state each provided to one or more memory banks, activated when corresponding memory bank(s) are in an active state, and deactivated when corresponding memory bank(s) are in a standby state, where n is an integer more than 1; m internal voltage generation circuits for standby state each provided to one or more memory banks, activated when corresponding memory bank(s) are at least in the standby state, where m is an integer more than 1; and a power supply wiring network supplying an internal voltage generated by the internal voltage generation circuits for active state and the internal voltage generation circuits for standby state to the corresponding memory banks.

In the present invention, it is preferable that the power supply wiring network is configured to include m sub-wiring networks corresponding to the m internal voltage generation circuits for standby state, respectively. In this case, the m sub-wiring networks maybe independent from one another. Alternatively, the power supply wiring network includes a connecting unit connecting the sub-wiring networks to one another. Preferably, the connecting unit is arranged in a peripheral portion of a chip.

According to the present invention, the semiconductor memory device includes a plurality of internal voltage generation circuits for standby state each provided to correspond to one or two or more memory banks. Due to this, even if the power supply wiring network is configured to include a plurality of sub-wiring networks, it is difficult to cause a voltage fluctuation in the power supply wiring network in the standby state. It is, therefore, possible to stabilize the internal voltage while greatly reducing the number of power supply wirings arranged in peripheral circuit regions.

### BRIEF DESCRIPTION OF THE DRAWINGS

The above and other objects, features and advantages of this invention will become more apparent by reference to the following detailed description of the invention taken in conjunction with the accompanying drawings, wherein:

FIG. 1 is a schematic plan view showing a configuration of a semiconductor memory device according to a first embodiment of the present invention;

FIG. 2 is a circuit diagram of an internal voltage generation circuits for active state;

FIG. 3 is a circuit diagram of an internal voltage generation circuits for standby state;

FIG. 4 is a circuit diagram of the comparator included in the internal voltage generation circuit for active state shown in FIG. 2;

FIG. 5 is a circuit diagram of the comparator included in the internal voltage generation circuit for standby state shown in FIG. 3;

FIG. 6 is a schematic plan view showing a configuration of the semiconductor memory device according to a second embodiment of the present invention; and

FIG. 7 is a schematic plan view showing a configuration of the semiconductor memory device according to a third embodiment of the present invention.

### DETAILED DESCRIPTION OF THE EMBODIMENTS

Preferred embodiments of the present invention will now be described below in detail with reference to the accompanying drawings.

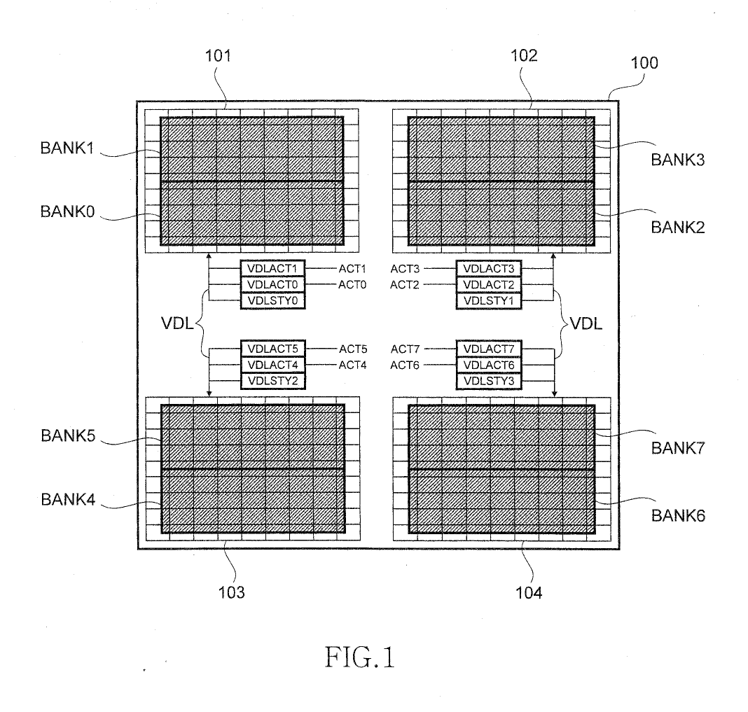

FIG. 1 is a schematic plan view showing a configuration of a semiconductor memory device according to the first embodiment of the present invention.

The semiconductor memory device according to the first embodiment is, for example, a DRAM. As shown in FIG. 1, a memory cell array is divided into eight memory banks BANK0 to BANK7. Commands can be individually issued from outside of a chip 100 to the respective memory banks BANK0 to BANK7. The memory banks BANK0 to BANK7 have different active periods accordingly.

In the first embodiment, the eight memory banks BANK0 to BANK7 are classified into four groups and the four groups are arranged to be distributed on the chip 100. Specifically, the memory banks BANK0 and BANK1 are grouped to be arranged on an upper left side of the chip 100. The memory banks BANK2 and BANK3 are grouped to be arranged on an upper right side of the chip 100. The memory banks BANK4 and BANK5 are grouped to be arranged on a lower left side of the chip 100. The memory banks BANK6 and BANK7 are grouped to be arranged on a lower right side of the chip 100.

On the chip 100, remaining regions located between the groups are used as peripheral circuit regions in which peripheral circuits such as a controller and a decoder are arranged.

As shown in FIG. 1, the semiconductor memory device according to the first embodiment includes a power supply wiring network configured to include sub-wiring networks 101 to 104. The power supply wiring network is a wiring network for supplying an internal voltage VDL to each of the memory banks BANK0 to BANK7, and constituted by upper wirings arranged to spread over the memory cell array. The sub-wiring networks 101 to 104 are formed on the corresponding groups, respectively and arranged independently of one another. Namely, wirings connecting the sub-wiring networks 101 to 104 to one another are not provided.

To supply the internal voltage VDL to the sub-wiring networks 101 to 104, the internal voltage generation circuits for active state VDLACT1 to VDLACT7 (hereinafter, generically “VDLACT”) and the internal voltage generation circuits for standby state VDLSTY1 to VDLSTY3 (hereinafter, generically “VDLSTY”) are employed.

Specifically, the internal voltage generation circuits for active state VDLACT0 and VDLACT1 and the internal voltage generation circuit for standby state VDLSTY0 are allocated to correspond to the sub-wiring network 101. The internal voltage generation circuits for active state VDLACT2 and VDLACT3 and the internal voltage generation circuit for standby state VDLSTY1 are allocated to correspond to the sub-wiring network 102. The internal voltage generation circuits for active state VDLACT4 and VDLACT5 and the internal voltage generation circuit for standby state VDLSTY2 are allocated to correspond to the sub-wiring network 103. The internal voltage generation circuits for active state VDLACT6 and VDLACT7 and the internal voltage generation circuit for standby state VDLSTY3 are allocated to correspond to the sub-wiring network 104.

Bank active signals ACT0 to ACT7 (hereinafter, generically “ACT”) are supplied to the internal voltage generation circuits for active state VDLACT0 to VDLACT7, respectively. The bank active signals ACT0 to ACT7 are signals activated when the corresponding memory banks BANK1 to BANK7 are to be activated, respectively. The internal voltage generation circuits for active state VDLACT0 to VDLACT7 start supplying the internal voltage VDL to the corresponding sub-wiring networks 101 to 104 when the corresponding bank active signals ACT0 to ACT7 are activated, respectively. In the other periods, i.e., in periods where the corresponding memory banks BANK0 to BANK7 are on standby, the respective internal voltage generation circuits for active state VDLACT0 to VDLACT7 stop supplying the internal voltage VDL to the corresponding sub-wiring networks 101 to 104. A power supply capability of each of the internal voltage generation circuits for active state VDLACT0 to VDLACT7 is designed so as to supply enough power consumed when the corresponding memory bank is in the active state.

Meanwhile, the internal voltage generation circuits for standby state VDLSTY0 to VDLSTY3 are circuits constantly supplying the internal voltage VDL to the corresponding sub-wiring networks 101 to 104, respectively. A power supply capability of each of the internal voltage generation circuits for standby state VDLSTY0 to VDLSTY3 is designed so as to stabilize the internal voltage VDL by compensating for a leakage current in a period where the corresponding memory bank is on standby state. In the semiconductor memory device according to the first embodiment, the power supply wiring network is configured to include the four sub-wiring networks 101 to 104. Due to this, a load imposed on the semiconductor memory device when one of the sub-wiring networks 101 to 104 is on standby is considerably light. It is, therefore, possible to design the semiconductor memory device so that an occupation area of each of the internal voltage generation circuits for standby state VDLSTY0 to VDLSTY3 is sufficiently small.

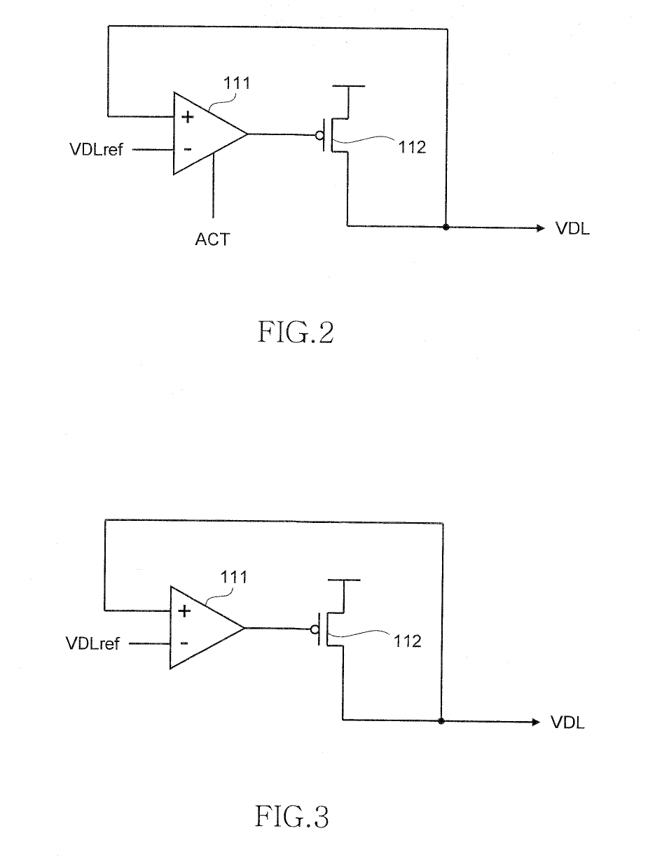

FIG. 2 is a circuit diagram of each of the internal voltage generation circuit for active state VDLACT. FIG. 3 is a circuit diagram of each of the internal voltage generation circuit for standby state VDLSTY.

As shown in FIGS. 2 and 3, the internal voltage generation circuit for active state VDLACT and the internal voltage generation circuit for standby state VDLSTY are almost identical in circuit configuration. Namely, each of the internal voltage generation circuit for active state VDLACT and the internal voltage generation circuit for standby state VDLSTY is configured to include a comparator 111 comparing a reference voltage VDLref with the internal voltage VDL and a P channel MOS transistor 112 controlled by an output of the comparator 111. However, the internal voltage generation circuit for active state VDLACT and the internal voltage generation circuit for standby state VDLSTY differ in the following respect. The corresponding bank active signal ACT is supplied to the comparator 111 included in the internal voltage generation circuit for active state VDLACT, and the comparator 111 performs a comparison operation only in a period where the bank active signal ACT is active. No such activation signal is supplied to the comparator 111 included in the internal voltage generation circuit for standby state VDLSTY, so that the comparator 111 constantly performs a comparison operation.

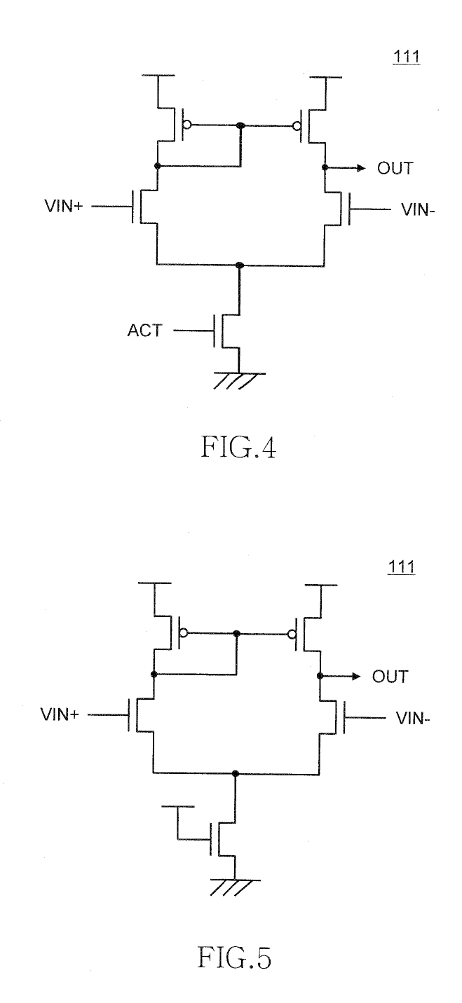

FIG. 4 is a circuit diagram of the comparator 111 included in the internal voltage generation circuit for active state VDLACT. FIG. 5 is a circuit diagram of the comparator 111 included in the internal voltage generation circuit for standby state VDLSTY. As shown in FIGS. 4 and 5, each of the comparators 111 is configured to include a differential amplifier circuit. However, in the circuit diagram of FIG. 4, the bank active signal ACT is supplied to a gate of an N channel MOS transistor constituting a current source. In the circuit diagram of FIG. 5, a gate of an N channel MOS transistor constituting a current source is fixed to high level.

With these configurations, each of the internal voltage generation circuit for active state VDLACT and the internal voltage generation circuit for standby state VDLSTY turns the transistor 112 on to raise the internal voltage VDL when the internal voltage VDL is reduced to be lower than the reference voltage VDLref. The internal voltage VDL applied to the sub-wiring networks 101 to 104 can be thereby kept almost constant.

The semiconductor memory device according to the first embodiment is configured as described above. In this manner, in the semiconductor memory device according to the first embodiment, the power supply wiring network is divided into the four sub-wiring networks 101 to 104 to correspond to the groups of the memory banks BANK0 to BANK7, and the internal voltage generation circuits for standby state VDLSTY0 to VDLSTY3 are provided to correspond to the sub-wiring networks 101 to 104, respectively. Due to this, there is no need to arrange many power supply wirings in the peripheral circuit regions as compared with the conventional semiconductor memory device, and it is possible to improve wiring utilization efficiency in the peripheral circuit regions.

A semiconductor memory device according to a second embodiment of the present invention will be described next.

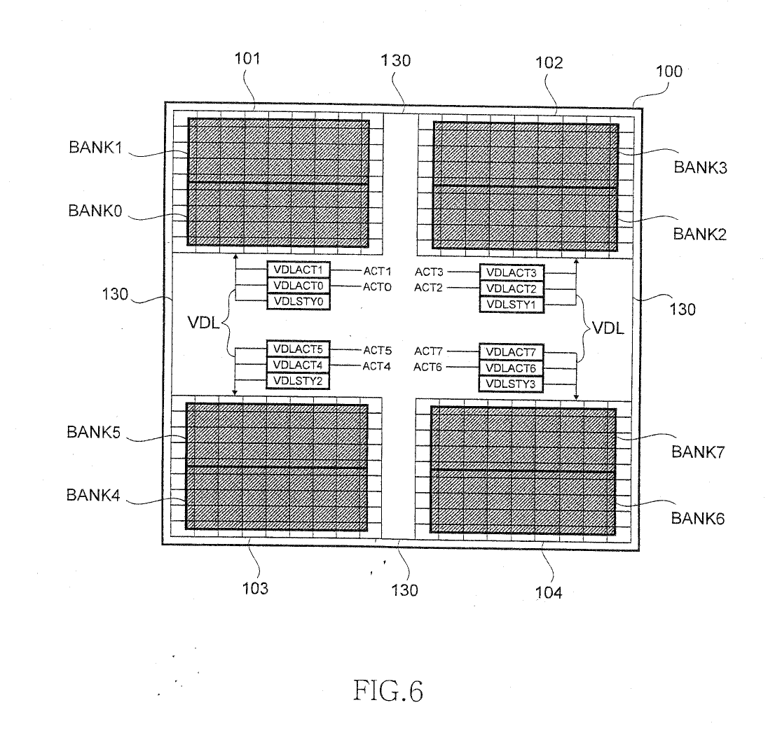

FIG. 6 is a schematic plan view showing a configuration of the semiconductor memory device according to the second embodiment of the present invention.

The semiconductor memory device according to the second embodiment differs from the first embodiment in that a connecting unit 130 connecting the sub-wiring networks 101 to 104 to one another is employed. Since other features of the second embodiment are identical to those of the first embodiment, like elements are denoted by like reference numerals and redundant explanations thereof will be omitted.

As shown in FIG. 6, the connecting unit 130 is arranged on peripheral portions of the chip 100. Due to this, the presence of the connecting unit 130 hardly causes deterioration in the wiring utilization efficiency in the peripheral circuit regions. In this manner, by connecting part of the sub-wiring networks 101 to 104 to one another while dividing the power supply wiring network into a plurality of sub-wiring networks 101 to 104, a power supply capacity is increased. It is, therefore, possible to further stabilize the internal voltage VDL.

A semiconductor memory device according to a third embodiment of the present invention will be described next.

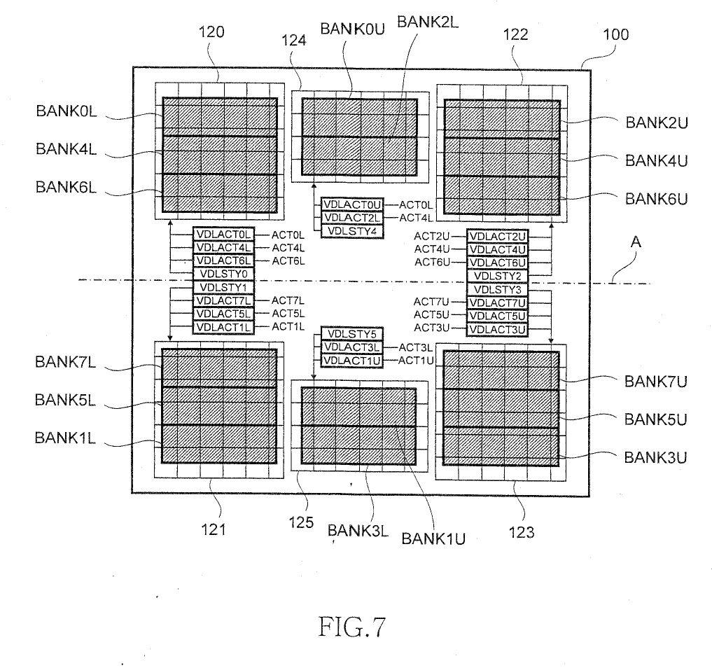

FIG. 7 is a schematic plan view showing a configuration of the semiconductor memory device according to the third embodiment of the present invention.

In the semiconductor memory device according to the third embodiment, memory banks BANK0 to BANK7 are divided into low-side memory banks BANK0L to BANK7L and high-side memory banks BANK0U to BANK7U. The low-side memory banks BANK0L, BANK4L, and BANK6L are arranged in an upper left area on the chip 100, the low-side memory banks BANK1L, BANK5L, and BANK7L are arranged in a lower left area on the chip 100, the high-side memory banks BANK2U, BANK4U, and BANK6U are arranged in an upper right area on the chip 100, the high-side memory banks BANK3U, BANK5U, and BANK7U are arranged in a lower right area on the chip 100. Further, the memory banks BANK0U and BANK2L are arranged in an upper central area on the chip 100 and the memory banks BANK1U and BANK3L are arranged in a lower central area on the chip 100. Namely, in the third embodiment, the eight divided low-side memory banks BANK0L to BANK7L and the eight divided high-side memory banks BANK0U to BANK7U are classified into six groups, and the six groups are arranged to be distributed on the chip 100.

By so arranging, the even-number memory banks are arranged in an upper area and the odd-number memory banks are arranged in a lower area across a central line A vertically dividing the chip 100. Moreover, the low-side memory banks BANK0L to BANK7L are arranged in a left area on the chip 100 whereas the high-side memory banks BANK0U to BANK7U are arranged in a right area on the chip 100. If such a floor plan is adopted, peripheral circuits can be arranged at the center of the chip 100 in a centralized fashion. It is thereby possible to make a plane shape of the chip 100 similar to a square shape and to suppress a difference between far ends and near ends to be small.

In the third embodiment, similarly to the first and second embodiments, the power supply wiring network is divided into sub-wiring networks 120 to 125 and the sub-wiring networks 120 to 125 are formed on the corresponding groups, respectively. The sub-wiring networks 120 to 125 can be arranged to be independent of one another similarly to the first embodiment or short-circuited by a connecting unit similarly to the second embodiment.

In the third embodiment, the number of banks that constitute each group differs among the groups. Namely, for the groups located on the left or right side of the chip 100, one group is constituted by the three banks. For the groups located at the center of the chip 100, one group is constituted by the two banks. Due to this, loads imposed on the internal voltage generation circuits and power supply capacities thereof differ among the sub-wiring networks 120 to 125.

In this case, it is preferable to set power supply capabilities of the corresponding internal voltage generation circuits for active state VDLACT or internal voltage generation circuits for standby state VDLSTY differently according to the number of banks included in the respective groups. Specifically, the power supply capabilities of the internal voltage generation circuits corresponding to the groups located on the left or right side can be set relatively high, and those of the internal voltage generation circuits corresponding to the groups located at the center can be set relatively low. It is thereby possible to supply power to the respective groups with appropriate capabilities.

While a preferred embodiment of the present invention has been described hereinbefore, the present invention is not limited to the aforementioned embodiment and various modifications can be made without departing from the spirit of the present invention. It goes without saying that such modifications are included in the scope of the present invention.

For example, the internal voltage generation circuits for standby state VDLSTY are constantly activated in the first to third embodiments described above. However, it suffices to activate the internal voltage generation circuits for standby state VDLSTY if at least the corresponding memory banks are on standby. Therefore, the internal voltage generation circuits for standby state VDLSTY can be deactivated while the corresponding memory banks are active.

Moreover, the number of memory banks is eight in the first to third embodiments, the number of groups is four in the first and second embodiments, and the number of groups is six in the third embodiment. However, the present invention is not limited to these numbers. Namely, as long as the number of groups is two or more, these numbers can be set arbitrarily. Accordingly, the memory banks can be as many as the groups. Besides, it is not always necessary to set the number of memory banks constituting each group to be equal.

Furthermore, one internal voltage generation circuit for active state is allocated per memory bank in the first and second embodiments. However, the present invention is not limited to the configuration. Therefore, one internal voltage generation circuit for active state can be allocated to correspond to, for example, two or more memory banks. As described in the third embodiment, two or more internal voltage generation circuits for active state can be allocated per memory bank.

Further, in the second embodiment, the sub-wiring networks 101 to 104 are connected to one another by forming the connecting unit 130 on the peripheral portions of the chip 100. However, the position of the connecting unit 130 is not limited to that described in the second embodiment. For example, if a region in which wirings can be further formed remains after completion of layout of necessary signal wirings, the connecting unit 130 can be arranged to pass through the region.

What is claimed is:

1. A semiconductor memory device comprising:
a plurality of memory banks;
n internal voltage generation circuits for active state each provided to one or more memory banks, activated when corresponding memory bank(s) are in an active state, and deactivated when corresponding memory bank(s) are in a standby state, where n is an integer more than 1;
m internal voltage generation circuits for standby state each provided to one or more memory banks, activated when corresponding memory bank(s) are at least in the standby state, where m is an integer more than 1; and
a power supply wiring network supplying an internal voltage generated by the internal voltage generation circuits for active state and the internal voltage generation circuits for standby state to the corresponding memory banks.

2. The semiconductor memory device as claimed in claim 1, wherein the m is smaller than the n.

3. The semiconductor memory device as claimed in claim 1, wherein the power supply wiring network is configured to include m sub-wiring networks corresponding to the m internal voltage generation circuits for standby state, respectively.

4. The semiconductor memory device as claimed in claim 3, wherein the plurality of memory banks are divided into m groups corresponding to the m sub-wiring networks, and numbers of memory banks included in at least two groups differ from one another.

5. The semiconductor memory device as claimed in claim 4, wherein each of the internal voltage generation circuits for active state or the internal voltage generation circuits for standby state corresponding to a group including relatively a large number of memory banks is higher in a power supply capability than each of the internal voltage generation circuits for active state or the internal voltage generation circuits for standby state corresponding to a group including relatively a small number of memory banks.

6. The semiconductor memory device as claimed in claim 3, wherein the m sub-wiring networks are independent from one another.

7. The semiconductor memory device as claimed in claim 3, wherein the power supply wiring network includes a connecting unit connecting the sub-wiring networks to one another.

8. The semiconductor memory device as claimed in claim 7, wherein the connecting unit is arranged in a peripheral portion of a chip.

9. The semiconductor memory device as claimed in claim 1, wherein the internal voltage generation circuits for standby state are activated irrespectively of whether the corresponding memory banks are in the standby state or in the active state.
